(19) United States
(12) Patent Application Publication
(10) Pub. No.: US 2013/0287529 A1
(43) Pub. Date: Oct. 31, 2013

(54) METHOD AND APPARATUS FOR INDEPENDENT WAFER HANDLING

(71) Applicants: Yao-Hung YANG, Santa Clara, CA (US); Jeonghoon OH, San Jose, CA (US); Frank F. HOOSHDARAN, Pleasanton, CA (US); Tom K. CHO, Los Altos, CA (US); Tao HOU, Palo Alto, CA (US); Yuanhung GUO, San Jose, CA (US)

(72) Inventors: Yao-Hung YANG, Santa Clara, CA (US); Jeonghoon OH, San Jose, CA (US); Frank F. HOOSHDARAN, Pleasanton, CA (US); Tom K. CHO, Los Altos, CA (US); Tao HOU, Palo Alto, CA (US); Yuanhung GUO, San Jose, CA (US)

(73) Assignee: APPLIED MATERIALS, INC., Santa Clara, CA (US)

(21) Appl. No.: 13/841,738

(22) Filed: Mar. 15, 2013

Related U.S. Application Data
(60) Provisional application No. 61/639,741, filed on Apr. 27, 2012.

(51) Int. Cl. H01L 21/677; H01L 21/683

(52) U.S. Cl. CPC H01L 21/67739; H01L 21/683
USPC 414/222.09; 414/222.13; 269/14

(57) ABSTRACT

A substrate processing system with independent substrate placement capability to two or more substrate support assemblies is provided. Two different sets of fixed-length lift pins are disposed on two or more substrate support lift pin assemblies of two or more process chambers, where the length of each lift pin in one process chamber is different from the length of each lift pin in another process chamber. The substrate processing system includes simplified mechanical substrate support lift pin mechanisms and minimum accessory parts cooperating with a substrate transfer mechanism (e.g., a transfer robot) for efficient and independent loading, unloading, and transfer of one or more substrates between two or more processing regions in a twin chamber or between two or more process chambers. A method for positioning one or more substrates to be loaded, unloaded, or processed independently or simultaneously in two or more processing regions or process chambers is provided.

### CROSS-REFERENCE TO RELATED APPLICATIONS

This application claims benefit of U.S. provisional patent application Ser. No. 61/639,741, filed Apr. 27, 2012, which is herein incorporated by reference.

### BACKGROUND OF THE INVENTION

1. Field of the Invention

Embodiments of the invention generally relate to apparatuses and methods for processing a semiconductor substrate and forming semiconductor devices. More particularly, embodiments of the invention relate to apparatus having a substrate support assembly and a substrate handling mechanism.

2. Description of the Related Art

In the field of integrated circuit and flat panel display fabrication, multiple deposition and etching processes are performed in sequence on a substrate among one or more process chambers to form various design structures. A substrate processing system may be equipped with multiple chambers for performing these processes, such as etching, physical vapor deposition (PVD), chemical vapor deposition (CVD), chamber cleaning and conditioning, etc. Thus, device fabrication on one or more substrates generally requires appropriate ways to deliver and transfer the substrates (e.g., wafer and other substrates) in a desirable order between different processing regions or process chambers within each substrate processing system. Substrate handling among various process chambers, pre-processing chambers, post-processing chambers, storage chambers, and other chambers can be a limiting factor in the capabilities of the substrate processing system. Time spent in substrate transfer, positioning, loading and unloading greatly impacts system throughput.

For example, a conventional semiconductor CVD system usually has both heater lift and wafer lift mechanisms to handle wafer transfer within a process chamber. FIGS. 1A and 1B are cross sectional views of two substrate support assemblies 40 disposed inside a process chamber 10. Each substrate support assembly 40 includes a stem 20 connected to a lift mechanism 26 which is configured to move the substrate support assembly 40 upward and downward in a vertical direction 28. Accordingly, the substrate support assembly 40 is movably positioned in a substrate processing region within the process chamber 10 between an elevated substrate processing position, as shown in FIG. 1A, and a lowered substrate transfer position, as shown in FIG. 1B.

The substrate support assembly 40 includes a support member 21 having a heating element 22 embedded therein for heating a substrate 12 disposed on a substrate support surface 23 of the support member 21. The substrate support assembly 40 may further include a lift pin assembly having a set of lift pins 50 being disposed through the support member 21. For example, the lift pins 50 may be configured to pass through a set of corresponding lift pin holes in the support member 21.

Each lift pin 50 has an upper end 51, which is substantially flush with or slightly recessed into the substrate support surface of the support member 21 when the substrate support assembly 40 is in the elevated substrate processing position as shown in FIG. 1A. Additionally, each lift pin 50 has a lower end 51, configured to extend beyond an under side of the support member 21 of the substrate support assembly 40. The upper end 51 of each lift pin 50 may be flared up or tapered to prevent each lift pin 50 from falling through the lift pin holes, when the set of lift pins 50 rests on the substrate support surface 23 of the support member 21 and moves together with the substrate support assembly 40, which in turn is moved by the actuator 26.

The set of lift pins 50 can be displaced by a lift pin plate 34 or a chamber bottom 14 and extended above the substrate support surface 23 of the support member 21 when the substrate support assembly 40 is lowered to near its lowered substrate transfer position. The lift pin plate 34 may be connected to a lift mechanism 36 configured to move the lift plate 34 (and the set of lift pins 50, which is displaced above the substrate support surface 23 of the support member 21) upward and downward in a vertical direction 38.

As shown in FIG. 1B, when the substrate support assembly 40 is lowered to a substrate transfer position, the lift pins 50 are extended above the substrate support surface 23 of the support member 21 such that a robot blade 16 of a transfer robot having one or more substrate contact regions 17 is able to move in a horizontal direction 18 inside the process chamber 10 on a horizontal substrate transfer plane “S” to load and unload the substrate.

In general, the set of lift pins 50 are vertically movable a proper distance above the substrate support surface 23 after loading an in-coming substrate or prior to unloading an out-going substrate by the transfer robot and assist in substrate transfer. It is desirable to minimize or eliminate the mechanical parts for actuating the lift pins. If the mechanical parts in moving and actuating the lift pins are eliminated, potential mechanical failure from these parts is reduced and the costs in manufacturing these complicated mechanical parts are saved.

Also, transfer robots in prior substrate processing systems are generally configured with multiple blades (e.g., dual blades), extending and retracting together into and out of two process chambers or two processing regions (e.g., a processing region 50A and a processing region 50B of the process chamber 10, such as a twin chamber) on a single substrate transfer plane (e.g., the horizontal substrate transfer plane “S”) to save time for substrate loading and unloading. However, when the substrate processing system is processing a group of substrates using a substrate processing sequence, there is often time a single substrate is left behind (e.g., a group of 25 substrates to be processed in a pair of two substrates at a time, leaving behind one substrate). Thus, there is a need for independent single substrate loading and unloading into and out of the two process chambers or two processing regions.

In addition, often time, there is a need to perform different processes or different substrate processing sequence on two or more substrates within the two or more process chambers or processing regions. Thus, there is a need to have a choice to load and unload either one or two substrates among processing regions or process chambers of a large substrate processing system, and still taking advantage of the time saving multi-blade movement of a transfer robot.

Accordingly, there is a need for an improved substrate processing system with simplified mechanical hardware and minimum accessory parts to cooperate with a substrate transfer mechanism (e.g., a multi-blade transfer robot) for efficient and independent substrate loading, unloading, and substrate transfer capability between two or more processing regions or process chambers.

### SUMMARY OF THE INVENTION

Embodiments of the invention provide substrate processing in two or more processing regions with two or more sets of lift pins having different lengths and being disposed on two or more substrate support assemblies to enable independent wafer placement capability and eliminate complicated mechanical parts for actuating various sets of the lift pins. In one aspect, a substrate processing system with independent substrate placement capability is configured with simplified mechanical hardware and minimum accessory parts to cooperate with a substrate transfer mechanism (e.g., a transfer robot) for efficient and independent substrate loading, unloading, substrate transfer between two or more process chambers, and independent substrate positioning in the two or more process chambers. In another aspect, mechanical designs of substrate positioning and lift pin mechanisms in two or more process chambers are improved by replacing movable lift pins with fixed-length lift pins adapted to rest (e.g., extending vertically upward in a distance about their own lengths) on a substrate support assembly and/or a chamber bottom in each process chamber, where the length of each lift pin in one process chamber is different from the length of each lift pin in another process chamber.

In one embodiment, a substrate processing system having two or more substrate processing regions is provided. The substrate processing system includes a first substrate support assembly disposed inside a first substrate processing region, a second substrate support assembly disposed inside a second substrate processing region, and a first set and a second set of lift pins. The first set of lift pins has a first length (L1) and is disposed through the first substrate support assembly. The second set of lift pins has a second length (L2) and is disposed through the second substrate support assembly. In one aspect, the second length (L2) is different from the first length (L1).

In another embodiment, a process chamber having two or more substrate processing regions is provided and includes a first substrate support assembly disposed inside a first substrate processing region, a second substrate support assembly disposed inside a second substrate processing region, a first set of lift pins having a first length (L1) and being disposed at least partially in the first substrate support assembly, and a second set of lift pins having a second length (L2) and being disposed at least partially in the second substrate support assembly, wherein the second length (L2) is different from the first length (L1).

A method for substrate processing is also provided to optimize substrate transfer and substrate processing operations between two or more process chambers. In one embodiment, a method for processing a substrate in a process chamber includes positioning a substrate support assembly to a vertically lower substrate transfer position such that a set of lift pins is positioned in a pop-up position configured to extend upwardly in its length above a surface of a bottom chamber body of the process chamber, pass through the substrate support assembly, and extend vertically a distance above a substrate support surface of the substrate support assembly. The method also includes transferring a substrate inside the process chamber in a first horizontal transfer plane, vertically lowering the substrate, thereby placing the substrate onto a set of lift pins positioned in its length in the pop-up position and a distance above a substrate support surface of the substrate support assembly; and vertically elevating the substrate support assembly, thereby retracting the set of lift pins within the substrate support assembly into a retracted position and engaging the substrate on the substrate support surface of the substrate support assembly. The method may further include positioning the substrate support assembly to a vertically higher substrate processing position. In one example, a transfer robot is configured to transfer the substrate inside the process chamber in the first horizontal transfer plane.

In another embodiment, the method further includes vertically moving the transfer robot downward, thereby placing the substrate onto the set of lift pins positioned in its length in the pop-up position and a distance above a substrate support surface of the substrate support assembly, and retracting the transfer robot out of the process chamber in a second horizontal transfer plane, which is vertically lower than the first horizontal transfer plane.

In still another embodiment, the method further includes positioning the substrate support assembly to the vertically lower substrate transfer position after the substrate is processed in the process chamber, thereby vertically lowering the substrate and positioning the set of lift pins from the retracted position to the pop-up position, placing the substrate onto the set of lift pins positioned in the pop-up position, moving the transfer robot inside the process chamber in the second horizontal transfer plane, which is vertically lower than the pop-up position of the set of the lift pins, vertically moving the transfer robot upward, thereby placing the substrate onto the transfer robot, and retracting the transfer robot having the substrate thereon out of the process chamber in the first horizontal transfer plane, which is vertically higher than the position of the set of the lift pins positioned in its length in the pop-up position and a distance above a substrate support surface of the substrate support assembly, and higher than the second horizontal transfer plane.

### BRIEF DESCRIPTION OF THE DRAWINGS

So that the manner in which the above recited features of the present invention can be understood in detail, a more particular description of the invention, briefly summarized above, can be had by reference to embodiments, some of which are illustrated in the appended drawings. It is to be noted, however, that the appended drawings illustrate only typical embodiments of this invention and are therefore not to be considered limiting of its scope, for the invention can admit to other equally effective embodiments.

FIG. 1A is a schematic cross-sectional view of two prior art substrate support assemblies positioned in a substrate processing position inside a process chamber.

FIG. 1B is another schematic cross-sectional view of one prior art substrate support assembly positioned in a substrate transfer position in a process chamber.

FIG. 2 illustrates one example of a substrate processing system having multiple process chambers, in accordance with one embodiment of the invention, where each process chamber includes two substrate support assemblies disposed in two substrate processing regions, and a transfer robot is adapted to independently load and unload one and/or two substrates onto the substrate support assemblies positioned in each process chamber.

FIG. 3A depicts a perspective view of one example of a transfer robot in accordance with one embodiment of the invention.

FIG. 3B depicts a side view of one example of a transfer robot in accordance with a different embodiment of the invention.

FIG. 3C depicts a top view of one example of a transfer robot in accordance with a different embodiment of the invention.

FIG. 4A illustrates a cross-sectional view of one embodiment of a transfer chamber having a transfer robot disposed therein and configured to move vertically, extend and retract horizontally through a slit valve assembly, and be positioned in and out of a processing region of a process chamber.

FIG. 4B illustrates a perspective view of one embodiment of a process chamber having a substrate support assembly disposed therein.

FIG. 5A is a cross-sectional view of one embodiment of a process chamber having a first substrate support assembly within a first processing region and/or a second substrate support assembly within a second processing region, the first and a second substrate support assemblies being positioned in a substrate processing position.

FIG. 5B is a cross-sectional view of another embodiment of a process chamber with independent substrate loading and unloading capability, with the first and a second substrate support assemblies being positioned in a substrate transfer position.

FIG. 6A is a cross cross-sectional view of one embodiment of a transfer robot capable of transferring one or more substrates on multiple substrate transfer planes in relation to the relative positions of two sets of lift pins positioned on a surface of a chamber bottom in two substrate processing regions of a process chamber.

FIG. 6B is a table illustrating the use of different substrate transfer planes by a transfer robot to place/load and remove/unload one and/or two substrates from a first substrate support assembly and a second substrate support assembly in accordance with one embodiment of the invention.

FIG. 6C illustrates a method for substrate processing using a transfer robot configured with more than one substrate transfer planes to place and remove a substrate onto and from a substrate support assembly having a set of lift pins (in a desired length) therein in accordance with one embodiment of the invention.

FIG. 7A is a top view of one embodiment of a transfer chamber and a twin process chamber showing a transfer robot in a retracted position ready for rotating within the transfer chamber or extending into another process chamber.

FIG. 7B is a top view of another embodiment of a transfer chamber and a twin process chamber showing a transfer robot in an extended position where two robot blades are positioned in two substrate processing regions of the process chamber.

FIG. 8A is a top view of a transfer chamber showing a time optimal path for a transfer robot rotating between process chambers disposed in opposite positions in a substrate processing system in accordance with one embodiment of the invention.

FIG. 8B is a top view of a transfer chamber showing a time optimal path for a transfer robot rotating between neighboring process chambers in accordance with one embodiment of the invention.

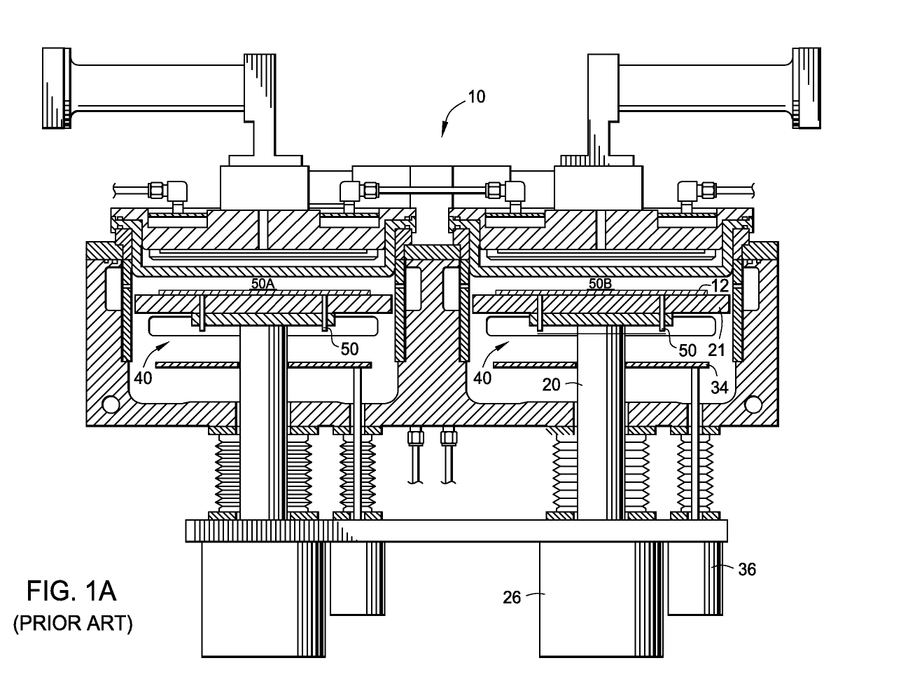

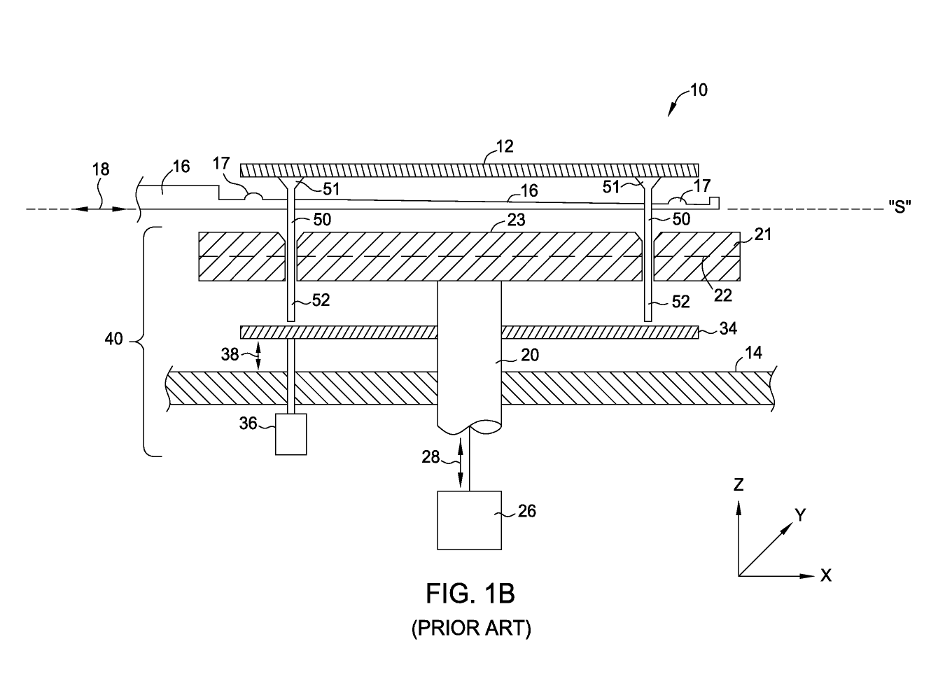

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the invention provide systems and methods for efficient substrate transfer and substrate processing among process chambers. A substrate processing system with independent substrate placement capability onto two or more substrate support assemblies is provided. The two or more substrate support assemblies are configured with simplified mechanical hardware and minimum accessory parts to cooperate with a substrate transfer mechanism (e.g., a transfer robot) for efficient and independent substrate loading, unloading, substrate transfer between two or more processing regions in a twin chamber or between two or more process chambers.

Two or more sets of lift pins are provided within the two or more substrate support assemblies of two or more process chambers, each set of lift pins has different lengths. For example, the length of each lift pin in one process chamber is different from the length of each lift pin in another process chamber. Complicated parts, such as lift plates, actuators, bellows, support stem collars are thus removed from the set of lift pins disposed on two or more substrate support assemblies, and thus potential mechanical failure due to these parts is reduced. By replacing movable lift pins with fixed-length stationary or passive movable lift pins disposed near a chamber bottom in each process chamber, the mechanical designs of the substrate positioning lift pin assemblies in two or more process chambers are improved and potential mechanical failure is reduced.

In one example, two different sets of fixed-length lift pins are disposed in close proximity to two substrate support assemblies inside two processing regions of a process chamber, (e.g., the length of each lift pin in one processing region is different from the length of each lift pin in another processing region). A method for independent substrate placement and substrate transfer in and out of the two or more processing regions or process chambers is also provided with a choice of one and/or two substrates to be loaded, unloaded, or processed. For example, a method for substrate processing is optimized by configuring a transfer robot to extend on multiple horizontal substrate transfer planes inside two or more processing regions of a process chamber for independent single substrate or multi-substrate transfer.

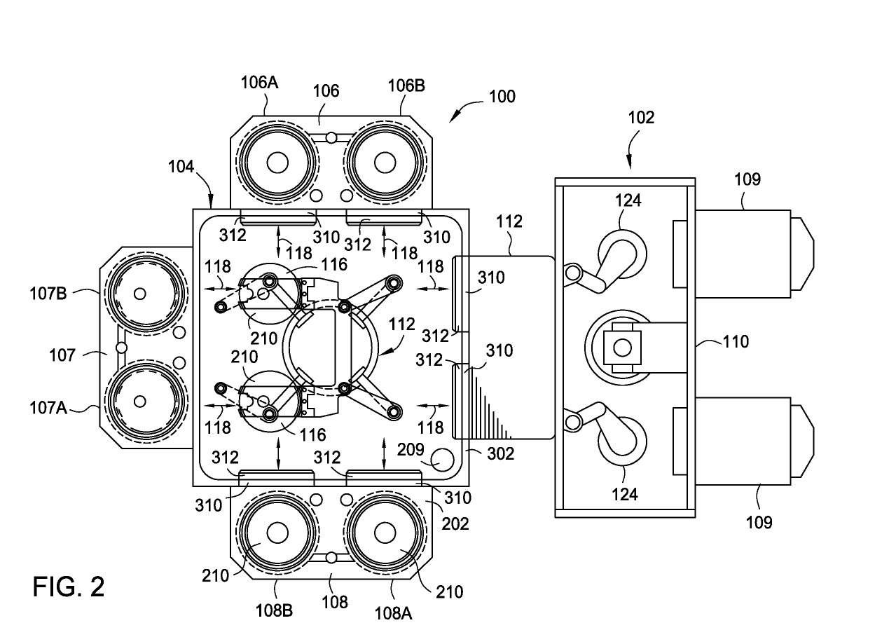

FIG. 2 illustrates one example of a substrate processing system 100 having multiple process chambers 106, 107, 108 mounted on a transfer chamber 104 with a transfer robot 112 disposed therein. In this embodiment, each process chamber 106, 107, 108 includes a substrate support assembly disposed in a substrate processing region formed within the chamber walls 202 of the process chambers 106, 107, 108.

In another embodiment, each process chamber 106, 107, 108 of the substrate processing system 100 includes two substrate support assemblies configured to concurrently process two substrates 210 disposed on two substrate support assemblies within substrate processing regions 106A, 106B, 107A, 107B, 108A, 108B. The substrate processing system 100 accordingly provides the advantages of single substrate process chambers and multiple substrates handling for high quality substrate processing, high substrate throughput and reduced system footprint.

The substrate processing system 100 may be a staged vacuum processing system and may generally include a front end staging area 102, where substrate cassettes 109 are positioned, a staging platform 110, where substrates 210 are loaded into and unloaded from a loadlock chamber 112 by one or more front end substrate handlers 124, and a back end area, where various utilities, such as gas panels, power distribution panels and power generators, required for the operation of the process chambers 106, 107, 108 are housed. Typically, the substrate processing system 100 is under vacuum, and the load lock chamber 112 can be “pumped down” and the substrates are then introduced into the substrate processing system 100. In addition, the loadlock chamber 112 may provide substrate pre-heating prior to substrate processing and/or substrate cooling after substrate processing. Details of the substrate processing system 100 are described in more detail in U.S. Pat. No. 6,635,115, by Fairbairn et al., and its related patent family, the disclosures of these US patents and patent applications are incorporated herein by reference.

Each process chamber 106, 107, 108 is configured to perform at least one substrate processing operation, such as chemical vapor deposition (CVD), cyclical layer deposition (CLD), atomic layer deposition (ALD), physical vapor deposition (PVD), preclean, etch, degas, orientation, pre-heat, surface treatments, annealing and other processes. The position of a process chamber utilized to perform a process relative to the other chambers is provided for illustration. The embodiment described below will be directed to a substrate processing system employing one or more CVD processes. However, it is to be understood that other processes and sequences are contemplated by the present invention.

Passages 310 are disposed in the sidewall of the loadlock chamber 112 and the walls 302 of the transfer chamber 104 to allow substrates 210 to be moved in a direction 118 (e.g., moving from the loadlock chamber 112 into the transfer chamber 104 or from the transfer chamber 104 into the process chambers 106, 107, 108). Slit valves 312 and slit valve actuators are used to seal the passages 310 when isolation or staged vacuum is desired. Slit valves and methods of controlling slit valves are disclosed by Tepman et al. in U.S. Pat. No. 5,226,632 and by Lorimer in U.S. Pat. No. 5,363,872, both of which are incorporated herein by reference.

Each process chamber 106, 107, 108 includes two or more substrate processing regions 106A, 106B, 107A, 107B, 108A, 108B, which are isolatable from each other and may share a common gas supply and a common exhaust pump. The processing regions 106A, 106B, 107A, 107B, 108A, 108B may have a confined plasma zone separate from the adjacent processing region which is selectively communicable with the adjacent substrate processing region via an exhaust system. The substrate processing regions 106A, 106B, 107A, 107B, 108A, 108B within each chamber 106, 107, 108 may include separate gas distribution assemblies and RF power sources to provide an uniform plasma density over a wafer surface in each processing region.

Accordingly, the process chambers 106, 107, 108 are configured to allow multiple, isolated processes to be performed concurrently in at least the two substrate processing regions of the process chamber so that a choice of one and/or two substrates can be processed simultaneously in separate substrate processing regions with a high degree of process control provided by shared gas sources, shared exhaust systems, separate gas distribution assemblies, separate RF power sources, and separate temperature control systems. For ease of description, the terms processing regions of a process chamber may be used to designate a zone or volume in which substrate processing is carried out.

The transfer chamber 104 generally contains the transfer robot 112 mounted to the bottom of the transfer chamber 104 via a central passage. The transfer chamber 104 may be maintained under ultrahigh vacuum conditions while allowing substrates 210 to be transferred and moved within the substrate processing system 100. A gas purge port 209 is disposed through the bottom of the transfer chamber 104 to provide a purge gas during pump down to maintain in a vacuum condition within the transfer chamber 104.

The transfer robot 112 contains at least two robot blades 116 adapted to independently load and unload one and/or two substrates onto one and/or two substrate support assemblies positioned in each process chamber 106, 107, 108. The term “substrate” as used herein generally includes any wafers, or other suitable glass, polymer, or metal substrates. A substrate may include a surface to be processed when disposed inside the substrate processing region 106A, 106B, 107A, 107B, 108A, 108B of the process chamber 106, 107, 108. Moreover, the substrate is not limited to any particular size or shape. The substrate can be a round wafer having a 200 mm diameter or a 300 mm or 450 mm diameter. The substrate can also be any polygonal, square, rectangular, curved or otherwise non-circular work-piece, such as a polygonal glass substrate used in the fabrication of flat panel displays.

Each substrate surface may include one or more layers of materials that serve as a basis for subsequent processing operations. For example, the substrate can include one or more layers of conductive metals, such as aluminum, copper, tungsten, or combinations thereof. The substrate can also include one or more layers of nonconductive materials, such as silicon, silicon oxide, doped silicon, germanium, gallium arsenide, glass, and sapphire. The substrate can also include layers of dielectric materials, such as silicon dioxide, organosilicates, and carbon doped silicon oxides. Further, the substrate can include any other materials such as metal nitrides and metal alloys, depending on the application. In one or more embodiments, the substrate can form a gate structure including a gate dielectric layer and a gate electrode layer to facilitate connecting with an interconnect feature, such as a plug, via, contact, line, and wire, subsequently formed thereon.

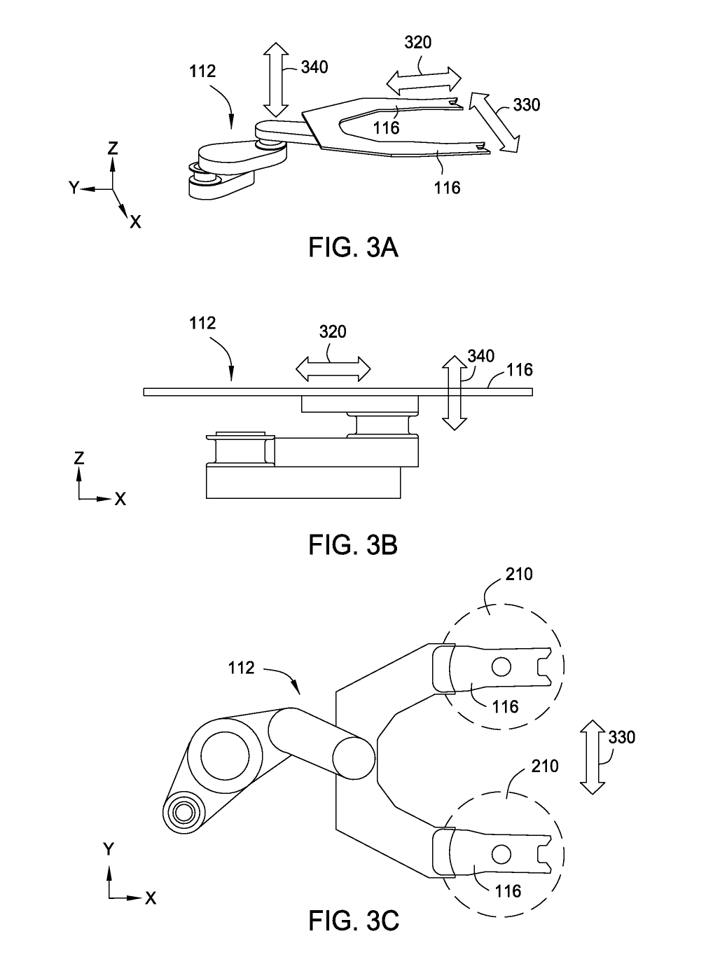

FIGS. 3A-3C illustrate one example of a transfer robot 112 that has the capability of moving one and/or two substrates disposed on one and/or two robot blades 116. The transfer robot 112 is configured to move vertically upward and downward in a direction 340 of the Z-axis. The transfer robot 112 is also capable of extending and retracting (e.g., in and out of each process chamber 106, 107, 108) horizontally in a direction 320 of the X-Y plane, as well as moving in side way horizontally in a direction 330 of the X-Y plane.

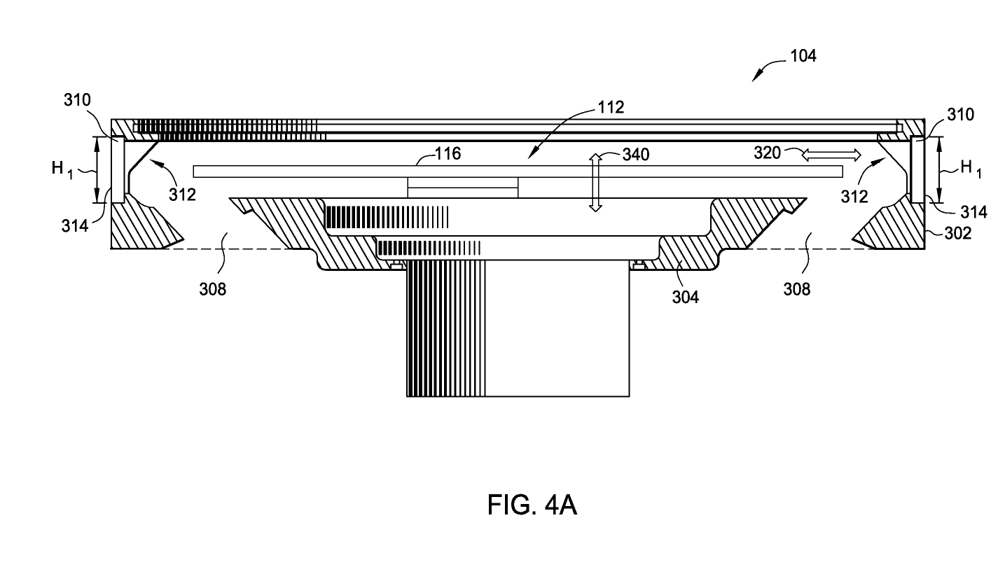

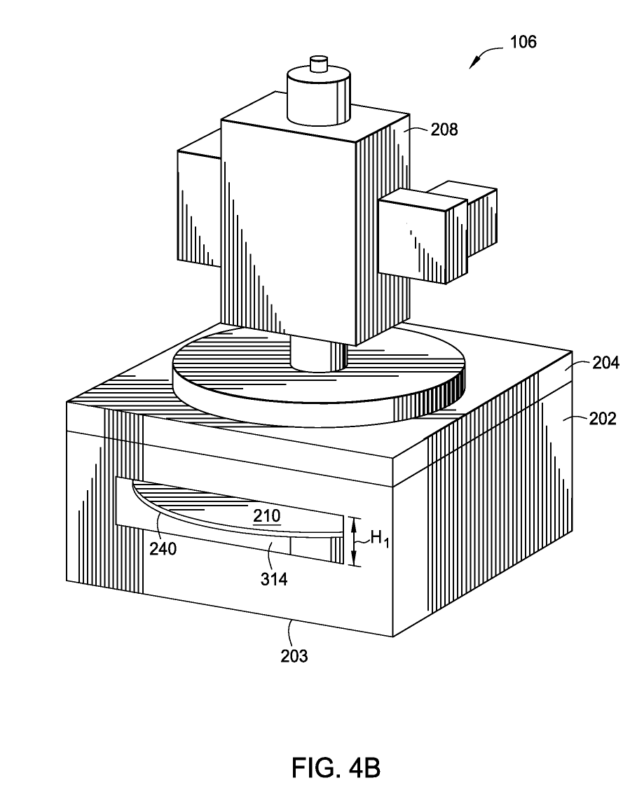

FIG. 4A illustrates one example of a transfer chamber 104 having the transfer robot 116 disposed therein and configured to move vertically, and extend and retract horizontally through slit valve assemblies disposed on the walls 302 of the transfer chamber 104 between the transfer chamber 104 and each of the process chambers 106, 107, 108. Each slit valve assembly includes a slit valve 312 and a slit valve actuator. The slit valve actuator is sealably mounted to a chamber bottom 304 of the transfer chamber 104, extends through one or more passages 308, and is adapted to actuate (e.g., open and close) the slit valve 312. The transfer robot is configured to extend and retract in the horizontal direction 320 to pass through a slit valve opening 314 for each slit valve 312 (when the slit valve 312 is open) via the passage 310 to be positioned in and out of a processing region of a process chamber.

In one embodiment, the transfer robot 112 as described herein is configured to extend and retract on multiple horizontal substrate transfer planes (as compared to prior single substrate transfer plane), taking advantage of the vertical movement capability (e.g., Z-axis motion in the direction 340) of the transfer robot 112. Each slit valve opening 314 of the slit valve 312 positioned between the transfer chamber 104 and each of the process chambers 106, 107, 108 may have a height “H₁”. Accordingly, the transfer robot 112 is configured to transfer substrates 210 on one or more horizontal substrate transfer planes, where the relative vertical positions of the one or more horizontal substrate transfer planes of the transfer robot are disposed within the slit valve opening 314 (with the height “H₁”) of the slit valve 312.

FIG. 4B illustrates one example of the process chamber 106 having a substrate processing region and a substrate support assembly disposed therein. The process chamber 106 includes chamber walls 202, a chamber bottom 203, a lid assembly 204, and a substrate support assembly 240 disposed therein. The process chamber 106 may be any type of process chambers known in the art for substrate processing, including etching, physical vapor deposition (PVD), chemical vapor deposition (CVD), chamber cleaning, substrate polishing, and conditioning, etc., where heating a surface of a substrate (e.g., a silicon substrate) disposed within the process chamber of a substrate processing system is involved. The process chamber 106 may be any substrate process chambers available from Applied Materials, Santa Clara, Calif. It is noted that other vacuum chambers available from other manufactures may also be utilized to practice the present invention.

The process chamber 106 generally includes the slit valve opening 314 formed in a sidewall of the chamber walls 202, and having a height “H₁”. The slit valve opening 314 can be selectively opened and closed by the slit valve 312 to provide access into the interior of the process chamber 106 by the transfer robot 112 and a substrate being carried by the transfer robot 112 is able to be loaded onto and unloaded from the substrate support assembly 240.

The chamber walls 202 may include a chamber liner that surrounds the substrate support assembly 240. The chamber liner may be removable for servicing and cleaning. The chamber liner can be made of a metal such as aluminum, a ceramic material, or any other process compatible material, and can be bead blasted to increase surface roughness and/or surface area which increases the adhesion of any material deposited thereon, thereby preventing flaking of material which results in contaminants of the process chamber 200. In addition, a pumping channel may be formed within the chamber liner.

In one embodiment, a set of lift pins at a desirable fixed length in the process chamber 106 are disposed near the substrate support assembly 240 to cooperate with the movements of the transfer robot 112 and the movements of the substrate support assembly 240 during substrate transfer, loading and unloading among the process chamber. In another embodiment, each set of lift pins disposed in one of the process chambers 106, 107, 108 within the substrate processing system 100 is configured to be in different length from another set of lift pins disposed in another chamber of the process chambers 106, 107, 108. Accordingly, parts, such as lift pin actuators, motors, lift plate, lift pin plate in the process chamber can be eliminated, thus avoiding possible mechanical failure of these components within the process chamber and saving equipment costs.

The lid assembly 204 may generally include a shower head assembly and one or more gas inlets connected thereto for flowing one or more gases through gas inlets of the shower head assembly to near the surface of the substrate 210 disposed on the substrate support assembly 240. The process gases may enter the lid assembly 204 via the one or more gas inlets, which are in fluid communication with one or more gas distribution system 208, which includes gas sources and/or other gas delivery components, such as gas mixers, generally disposed outside of the chamber walls 202. The lid assembly 204 may also include one or more gas outlets.

Optionally, the lid assembly 204 can include a distribution plate and a blocker plate for providing a controlled and evenly-distributed flow of gases through the shower head assembly onto the surface of the substrate 210 within the process chamber 106. The distribution plate may include one or more embedded channels or passages housing a heater or heating fluid to provide temperature control of the lid assembly 204. A resistive heating element (not shown) can be inserted within the channels to heat the distribution plate. A thermocouple can be connected to the distribution plate to regulate the temperature thereof. The thermocouple can be used in a feedback loop to control electric current applied to the heating element of the distribution plate. Alternatively, a heat transfer medium or a cooling medium, if needed, can be passed through the channels of the distribution plate to better control the temperature of the distribution plate within the lid assembly 204, depending on the process requirements within the process chamber 106. Any heat transfer medium may be used, such as nitrogen, water, ethylene glycol, or mixtures thereof, for example. In addition, the lid assembly 204 can be heated using one or more heat lamps (not shown). Typically, the heat lamps are arranged about an upper surface of the distribution plate to heat the components of the lid assembly 204, including the distribution plate, by radiation.

The process chamber 106 may include a vacuum pump and a throttle valve to regulate flow of gases inside the process chamber 106, flowing from gas sources via gas inlets disposed within the lid assembly 204 and the shower head assembly, to a processing region on the surface of the substrate 210. The vacuum pump is coupled to a vacuum port disposed on the chamber walls 202, and may also be connected or in fluid communication with the pumping channels of the chamber liner. Thus, the vacuum pump can be coupled to various mechanical chamber parts to provide an egress for any excess precursor gases or unwanted product gases or contaminants generated within the process chamber 106. The terms “gas” and “gases” are used interchangeably, unless otherwise noted, and refer to one or more precursors, reactants, catalysts, carrier, purge, cleaning, combinations thereof, as well as any other fluid introduced into the chamber walls 202.

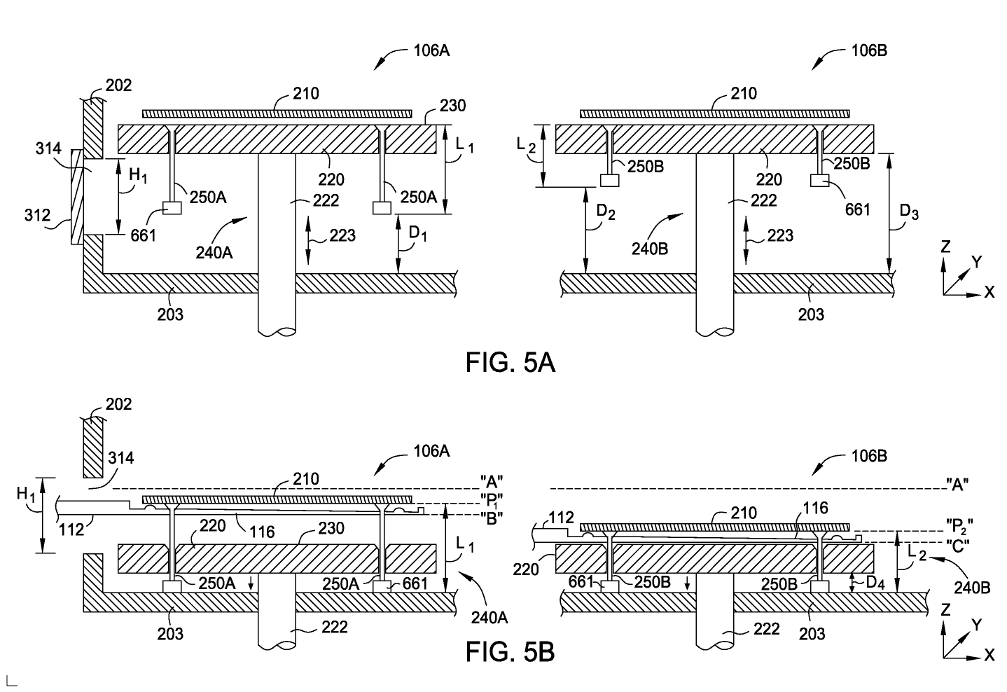

FIG. 5A illustrates side views of processing regions 106A and 106B of process chamber 106 having a first substrate support assembly 240A and a second substrate support assembly 240B each positioned in a substrate processing position. FIG. 5B illustrates the process chamber 106 as shown in FIG. 5A with the first substrate support assembly 240A and the second substrate support assembly 240B positioned in a substrate transfer position. In general, a substrate processing position of a substrate support assembly is vertically elevated and thus in a higher vertical position than a substrate transfer position so that a processing volume between a shower head assembly of a lid assembly and a substrate disposed on the substrate support assembly in the substrate processing position is small for uniform gas distribution and efficient substrate processing, as well as reducing the usage of process gases to fill the processing volume.

In one embodiment, the process chamber 106 has two substrate processing regions 106A, 106B and two substrate support assembly assemblies 240A, 240B are provided. In another embodiment, the process chamber 106 is adapted to process a choice of one and/or two substrates disposed on the first substrate support assembly 240A and/or the second substrate support assembly 240B and provides independent substrate loading and unloading capability into and/or out of the first and the second substrate processing regions 106A, 106B.

In general, each substrate support assembly 240A, 240B of the process chamber 106 may include a heating pedestal or a susceptor, which generally includes a shaft 222 and a support member 220. The shaft 222 extends through a centrally-located opening formed from the chamber bottom 203 and is generally disposed vertically within the bottom portion of the process chamber 106. The support member 220 has a substrate support surface 230 to support a substrate 210 to be processed thereon. For example, the support member 220 may have a flat or a substantially flat, circular or square surface for supporting a substantially circular or square substrate thereon. The support member 220 may be generally constructed of aluminum, or other suitable material. Optionally, the support member 220 can include a removable top plate made of some other material, such as silicon, ceramic, or other suitable material, for example, to reduce backside contaminants on the substrate.

The shaft 222 is connected to a lift mechanism (not shown) disposed outside of the chamber body. The lift mechanism moves the shaft 222 and the support member 220 vertically in a direction 223 (e.g., upwardly and downwardly) within the process chamber 206 between a vertically elevated substrate processing position, as shown in FIG. 5A, and a vertically lower substrate transfer position, as shown in FIG. 5B. In one embodiment, the substrate transfer position of the support member 220 is slightly below the slit valve opening 314 formed in the chamber walls 202. The lift mechanism of the shaft 222 can be flexibly sealed to the chamber bottom 203 by bellows that prevent vacuum leakage from around the shaft 222. The substrate support assembly 240A, 240B of the process chamber 106 is configured to heat and/or cool the substrate 210.

The substrate 210 may be secured to the support member 222 using a vacuum chuck, such as an electrostatic chuck. An electrostatic chuck typically includes at least a dielectric material that surrounds a chuck electrode (not shown), which may be located on an upper surface of the support member 220 or formed as an integral part of the support member 220. The dielectric portion of the electrostatic chuck electrically insulates the chuck electrode from the substrate 210 and from the remainder of the substrate support assembly.

In one or more embodiments, the support member 220 can include one or more bores (e.g., lift pin holes) formed therethrough to accommodate various sets of one or more lift pins 250A and 250B disposed in the first substrate support assembly 240A and the second substrate support assembly 240B, respectively. Each lift pin 250A, 250B is constructed of ceramic or ceramic-containing materials, and is used for substrate placement, substrate movement, and substrate transport within the first and the second substrate processing regions 106A, 106B of the process chamber 106.

The support member 220 can be moved vertically within the process chamber 106 by the lift mechanism connected thereto so that a distance between the support member 220 and the lid assembly 204 can be controlled (e.g., controlling the movement of the support member 220 to keep the distance short and thus a substrate processing volume small). A sensor (not shown) can provide information concerning the position of the support member 220 within the process chamber 200.

The support member 220 can further include an edge ring (not shown) disposed about the support member 220. The edge ring is an annular member that is adapted to cover an outer perimeter of the support member 220 and protect the support member 220 from deposition. The edge ring can be positioned on or adjacent the support member 220 to form an annular purge gas channel between the outer diameter of support member 220 and the inner diameter of the edge ring. The annular purge gas channel can be in fluid communication with a purge gas conduit formed through the support member 220 and the shaft 222. The purge gas conduit is in fluid communication with a purge gas supply (not shown) to provide a purge gas to the annular purge gas channel. Any suitable purge gas such as nitrogen, argon, or helium, may be used alone or in combination. During substrate processing operations, the purge gas flows through the purge gas conduit, into the annular purge gas channel, and about an edge of the substrate disposed on the support member 220. Accordingly, the purge gas working in cooperation with the edge ring prevents deposition at the edge and/or backside of the substrate.

The temperature of the substrate support surface 230 of each substrate support assembly 240A, 240B can also be controlled by a fluid circulated through a fluid channel embedded within the body of the support member 220. The fluid channel may be in fluid communication with a heat transfer conduit disposed through the shaft 222 of the substrate support assembly 240A, 240B. The fluid channel may be disposed inside and about the support member 220 to provide a uniform heat transfer to the substrate support surface 230 of the support member 220. The fluid channel and the heat transfer conduit can flow heat transfer fluids to either heat or cool the support member 220. Any suitable heat transfer fluid may be used, such as water, nitrogen, ethylene glycol, or mixtures thereof.

In operation, the support member 220 can be elevated to a close proximity with the lid assembly 204 to control the volume of a reaction space above a surface of the substrate 210 and the temperature of the substrate 210 being processed. As such, the substrate 210 can be processed using a mixture of process gases and/or heated via radiant heating emitted from the distribution plate of the lid assembly 204 or a heating element 212 embedded within the support member 220. In some cases, a plasma is employed in a plasma assisted CVD process to assist processing on the surface of the substrate 210.

During substrate processing, as shown in FIG. 5A, each lift pin 250A, 250B is disposed in a retracted position (e.g., being slightly recessed and seated in its respective bore or lift pin hole), when the substrate support assembly 240A, 240B is in its substrate processing position. In one embodiment, the lift pins 250A, 250B by themselves are not movable by any lift mechanism or actuator. However, the lift pins 250A, 250B can be moved vertically (e.g., upwardly and downwardly by an actuation force of a lift mechanism applied to the shaft 222 of the substrate assemblies 240A, 240B), together with the support member 220 of the substrate support assembly 240A, 240B, when each lift pin 250A, 250B is in its elevated position being seated on its respective lift pin hole (or bore) within the support member, as shown in FIG. 5A.

After processing, the substrate 210 can be lowered down by the lift mechanism of the shaft 222 to be away from the lid assembly 204 and further lifted off from the substrate support surface 230 of the support member 220 using the lift pins 250A, 250B. When each substrate support assembly 240A, 240B is actuated from its elevated substrate processing position to its lower substrate transfer position as shown in FIG. 5B, each lift pin 250A, 250B moves along with the support member 220 and is lowered vertically until an end (e.g., a bottom end 661) of each lift pin 250A, 250B eventually touches the chamber bottom 203 of the process chamber 106.

Each lift pin's length is configured to be long enough to be disposed vertically a distance higher than a plane of the substrate support surface 230 of the support member 222. When each substrate support assembly 240A, 240B is positioned in its lower substrate transfer position, each lift pin 250A, 250B is then supported by the chamber bottom 203 and stands up stationary on its own length. Thus, each lift pin 250A, 250B is lifted off (or popped up) from the substrate support surface 230 of the support member 220, when each lift pin 250A, 250B is standing on the chamber bottom 203 on its own length to be in its stationary pop-up position.

As shown in FIG. 5B, each lift pin 250A, 250B is disposed in its stationary pop-up position, being supported by the chamber bottom 203 and standing up stationary in its length, when the substrate support assembly 240A, 240B is in its substrate transfer position. A portion of the lift pin 250A, 250B may still be disposed through its respective bore. In one embodiment, the bottom end 661 of each lift pin 250A, 250B may be in a shape that is larger in shape or size (e.g., larger diameter) than each lift pin's respective bore such that the bottom end 661 is able to provide a space between the support member 220 of the substrate support assembly 240A, 240B and the chamber bottom 230.

In one or more embodiments, the two sets of lift pins 250A, 250B are at different lengths. As shown in the example of FIG. 5B, each lift pin 250A disposed near the first substrate support assembly 240A has a first length (L1) and each lift pin 250B disposed near the second substrate support assembly 240B has a second length (L2). In one embodiment, the first length L1 is different from the second length L2. Because of their different lengths, the relative vertical position of each lift pin 250A disposed in its stationary pop-up position within the substrate processing region 106A is different from the vertical position of each lift pin 250B disposed in its stationary pop-up position within the substrate processing region 106B.

In one or more embodiments, the process chamber 106 provides at least a first set of lift pins 250A configured to support a substrate 210 transferred thereon in a first stationary pop-up position (P1) within the first processing region 106A, when the first substrate support assembly 240A is lowered to a vertically lower substrate transfer position. In addition, the process chamber 106 provides at least a second set of lift pins 250B configured to support a substrate 210 transferred thereon in a second stationary pop-up position (P2) within the second processing region 106B, while the second substrate support assembly 240B is lowered to a vertically lower substrate transfer position.

During substrate transfer, a processed substrate is transferred out of the process chamber 106 by the transfer robot 112 and one and/or two substrates are loaded onto one and/or two substrate support assemblies 240A, 240B. Next, the shaft 222 may be moved vertically upwardly until each substrate support assembly 240A, 240B is moved to its substrate processing position. In one or more embodiments, each lift pin 250A, 250B can be moved upwardly together along with the support member 220 of the substrate support assembly 240A, 240B, when an end (e.g., an upper end 663) of each lift pin 250A, 250B is retracted inside its respective bore.

In one aspect, the upper end 663 of each lift pin is tapered or flared up upward such that each lift pin 250A, 250B can be disposed within the support member 220 in its retracted position as shown in FIG. 5A, (e.g., in a seated and slightly recessed manner into its respective bore/hole), with the bottom end 661 of the lift pin 250A, 250B hanging below the support member 220. The first and second sets of the lift pins 250A, 250B within the process chamber 106 of the substrate processing system 100 are configured to be retracted within the first and the second substrate support assemblies 240A, 250B, when the first and the second substrate support assembly are elevated to a vertically higher substrate processing position. It is believed that the difference in the lengths of the lift pins 250A, 250B in the substrate support assembly 240A, 240B don't affect normal substrate processing operations.

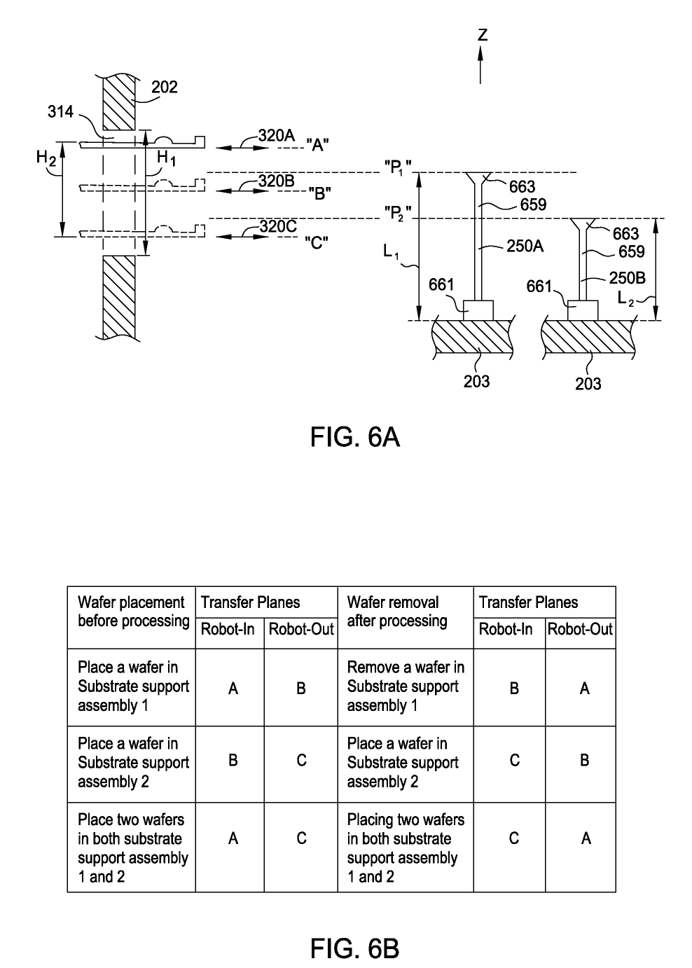

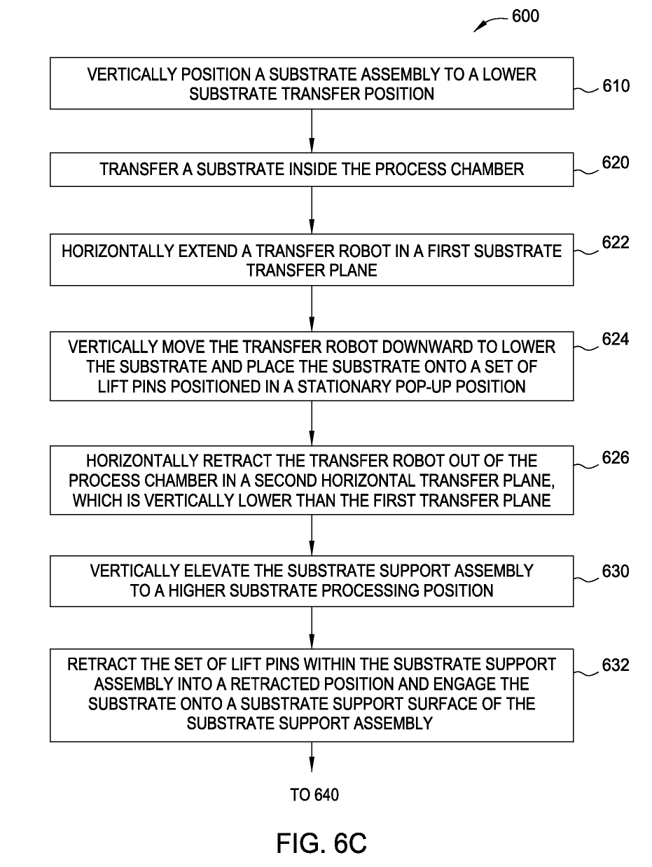

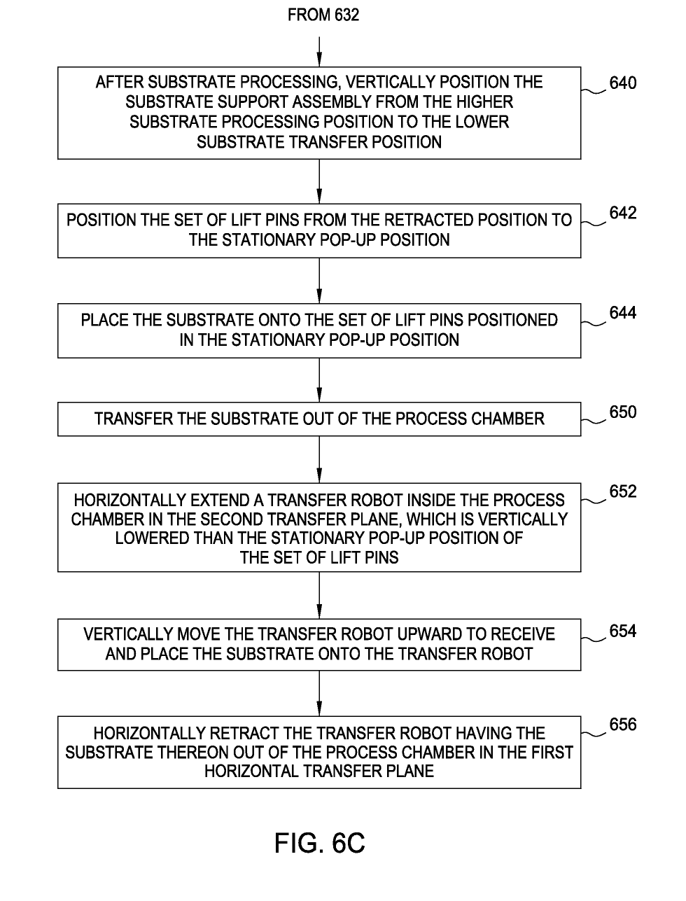

FIG. 6A is one example of the two sets of lift pins 250A, 250B being disposed on a surface of the chamber bottom 203 of the process chamber 106 in relation to substrate loading and unloading movements by the transfer robot 112. As shown in FIG. 6A, the two sets of lift pins 250A, 250B are structurally similar. Each lift pin 250A, 250B may include an upper end 663, a lift pin body 659, and a lower end 661. The upper end 663 may be tapered upward (or flared up) such that lift pins 250A, 250B are configured to be retracted within the first and the second substrate support assemblies 240A, 240B, when the first and the second substrate support assemblies 240A, 240B are elevated to a vertically higher substrate processing position.

As discussed above, the transfer robot 112 is capable of transferring a substrate on multiple substrate transfer planes (e.g., substrate transfer planes “A”, “B”, “C” as shown in FIG. 6A) as long as these planes are within the height “H₁” of the slit valve opening 314. In one example, the distance “H₂” between the upper substrate transfer plane “A” and the lower substrate transfer plane “C” of the transfer robot 112 is smaller than “H₁”.

The transfer robot 112 is configured with two or more robot blades 116, each robot blade 116 is configured to move vertically upward and downward and horizontally in first, second and third substrate transfer planes (e.g., the substrate transfer planes “A”, “B”, and “C”, as shown in FIG. 6A). For example, each robot blade 116 may extend and retract in a horizontal direction 320A, 320B, 320C, respectively in and out of the first substrate processing region 106A and the second substrate processing region 106B. In one embodiment, the two robot blades 116 of the transfer robot 112 are provided for loading or unloading substrates onto and being supported by the lift pins 250A, 250B, without directly placing the substrates onto the substrate support surface 230 of the support member 220.

Because two sets of lift pins are used and they are at different lengths, the transfer robot 112 may be configured to have a choice of placing one and/or two substrates 210 in one single loading movement onto a first set of lift pins 250A (being at a first stationary pop-up position (P₁), relative to a first length L1 from the chamber bottom 203, within the first processing region 106A), and/or a second set of lift pins 250B (being at a second stationary pop-up position (P₂), relative to a second length L2 from the chamber bottom 203, within the second processing region 106B).

In one or more embodiments, the transfer robot 112 is configured to move vertically and horizontally between the upper, middle, and lower transfer planes “A”, “B”, “C”, and has a choice to deliver one or two substrates onto or remove from the lift pins 250A and/or the lift pins 250B. In this way, each substrate can be independently aligned and placed in a substrate processing region of a process chamber.

FIG. 6B is a table illustrating the use of different substrate transfer planes “A”, “B”, “C” by the transfer robot 112 to place/load and remove/unload one and/or two substrates 210 from the first substrate support assembly 240A and the second substrate support assembly 240B. As shown in FIG. 6B, the transfer robot 112 may be configured to move vertically and horizontally between the substrate transfer planes “A” and “B” for independently placing and removing a single substrate (e.g., a wafer) onto and from the first substrate support assembly 240A of the first substrate processing region 106A, without loading a substrate onto the second substrate support assembly 240B. Also, the transfer robot 112 may be configured to move vertically and horizontally between the substrate transfer planes “B” and “C” for independently placing and removing a single substrate (e.g., a wafer) onto and from the second substrate support assembly 240B of the second substrate processing region 106B.

Accordingly, for transferring only one substrate, the transfer robot 112 equipped with two robot blades 116 is configured to use two different pairs of substrate transfer planes to differentiate which one of the substrate support assemblies 240A, 240B that it would perform a substrate transfer operation. In this case, the transfer robot 112 is configured to transfer one substrate using one robot blade independently, leaving another robot blade empty without any substrate thereon. In addition, since three horizontal substrate transfer planes can be used, the transfer robot can designate and differentiate which one of the two robot blades is used for which one of the two substrate support assemblies 240A, 240B in a single substrate transfer operation.

Conveniently, the transfer robot 112 described herein retain the capability of transferring two substrates simultaneously in and out of the first and the second substrate support assembly 240A, 240B in a dual substrate transfer operation. For example, the transfer robot 112 may be configured to move vertically and horizontally between the transfer planes “A” and “C” for placing and removing two (2) substrates onto and from both substrate support assemblies 240A, 240B of both substrate processing regions 106A, 106B. In this case, the transfer robot 112 is configured to use a different pair of substrate transfer planes for dual substrate transfer (e.g., a pair of transfer planes “A” and “C”), different from the pair of substrate transfer planes used for single substrate transfer (e.g., a pair of transfer planes “A” and “B” or a pair of “B” and “C”).

In one or more embodiments, substrate loading and unloading in and out of the first and the second substrate processing regions 106A, 106B of a single process chamber may be adapted to operate in and out of two substrate processing regions of two different process chambers in a substrate processing system. The process chambers may be any two of etch chambers, cleaning chambers, CVD chambers, PVD chambers, ALD chambers, pre-heating chambers, annealing chambers, and combinations thereof. The mechanical design as discussed herein may be applied to a process chamber for processing any 300 mm substrate, with the multiple substrate transfer planes of the transfer robot 112 being spaced within the height and dimension of the slit valve opening 314, as shown in FIG. 6A. The same substrate loading and unloading mechanism can also be used for the 200 mm, 450 mm, or any next generation process chambers.

FIG. 6C illustrates a method 600 for processing a substrate (e.g., the substrate 210) on a substrate support assembly of a process chamber (the process chamber 106, 107, 108, as shown in FIG. 2, or any other chamber) using a transfer robot configured with a capability of more than one substrate transfer planes for transferring one or more substrate at a time using its extending-retracting movement. For example, the transfer robot may be configured for transferring substrates with a choice of using one, two, three or more substrate transfer planes (e.g., two substrate transfer planes are used in the method 600 as described below). In one example, the transfer robot may be configured with a capability of using two substrate transfer planes and having a choice of transferring one or two substrates at a time. As another example, the transfer robot may be configured with a capability of using three substrate transfer planes and having a choice of transferring one or two substrate transfer planes at a time.

As shown in FIG. 6C, the method 600 may generally include a stage 610 of vertically positioning a substrate support assembly to a lower substrate transfer position, a stage 620 of transferring a substrate inside the process chamber, and a stage 630 of vertically elevating the substrate support assembly to a higher substrate processing position for performing substrate processing. After the substrate is processed, the method 600 may further include a stage 640 of vertically positioning the substrate support assembly from the higher substrate processing position to the lower substrate transfer position, and a stage 650 of transferring the substrate out of the process chamber.

At stage 610, when the substrate support assembly is lowered a substrate transfer position, a set of lift pins is positioned in a stationary pop-up position configured to extend upwardly (e.g., in a length equal to its own length) above a surface of a bottom chamber body of the process chamber, pass through the substrate support assembly, and extend vertically a distance above a substrate support surface of the substrate support assembly.

At stage 620, a substrate is transferred inside the process chamber. At this stage, a transfer robot may be used at step 622 to load a substrate into the process chamber. The transfer robot is configured to extend and retract in multiples horizontal transfer planes. For example, the transfer robot may be configured with one or more robot blades, and each robot blade capable of supporting a substrate thereon. The transfer robot may extend its multiple robot blades in a first horizontal substrate transfer plane to pass through a slit valve opening of the process chamber until the one or more robot blades are atop the substrate support assembly.

Next, at step 624, the transfer robot (e.g., capable of vertical movements and configured with multiple horizontal substrate transfer planes) may move vertically downward. Thus, the substrate disposed on the robot blade is also vertically lowered down until the substrate is placed onto the set of lift pins positioned in the stationary pop-up position.

At step 626, after the substrate is loaded and supported by the set of the lift pins, the transfer robot can retract horizontally out of the process chamber in a second horizontal substrate transfer plane. The second horizontal substrate transfer plane is configured to be vertically lower than the first horizontal transfer plane, and also vertically lower than a plane of the set of lift pins positioned upwardly in their length in the stationary pop-up position.

Next, at stage 630, the substrate support assembly is vertically elevated (e.g., by a lift mechanism connected to the shaft of the substrate support assembly). At step 632, the set of lift pins within the substrate support assembly may passively recess into their respective bores (e.g., lift pin holes disposed in a support member of the substrate support assembly). Eventually, the set of lift pins may retract into a retracted position within their respective bores such that the substrate supported by the set of lift pins are engaged onto the substrate support surface of the substrate support assembly. As the substrate support assembly is actively movable (e.g., using the lift mechanism as discussed above) and the set of lifts pins are not connected to any lift mechanism directly, each lift pin may then be moved passively and upwardly along with the substrate support assembly during stage 630. At the end of stage 630, the substrate support assembly is moved upwardly until it is positioned vertically in a substrate processing position. At this time, the surface of the substrate is ready to be processed.

Next, at stage 640, after substrate processing, the substrate support assembly may move vertically downward, moving along the substrate disposed thereon. At the same time, the set of lift pins disposed within their respective bores in a retracted position is also moving along with the substrate support assembly and vertically lowered. During the stage 640, the substrate support assembly may move vertically downward, the set of lift pins is then moving passively along with the substrate support assembly. At step 642, the set of lift pins is positioned from its reacted position to its stationary pop-up position. It is designed that the relative vertical position of each lift pin in its stationary pop-up position (e.g., standing on its length on top of the chamber bottom) is higher than the relative vertical position of the substrate support assembly in a substrate transfer position. Eventually, at the end of the stage 640 of lowering the substrate support assembly, the substrate support assembly may be positioned to its vertically lower substrate transfer position. As such, at step 644, the substrate disposed on the substrate support assembly is passed onto and supported by the set of lift pins in its stationary pop-up position.

Then, after the substrate is processed in the process chamber, and supported by the set of the lift pins, at stage 650, the substrate is ready to be transferred out of the process chamber. At step 652, the transfer robot is used to horizontally extend its robot blade inside the process chamber in the second horizontal transfer plane. It is designed that the second horizontal transfer plane is vertically lower than the pop-up position of the set of the lift pins.

At step 654, the robot blade of the transfer robot may move vertically upward from the second horizontal transfer plane to the first horizontal transfer plane, thereby placing the substrate onto the robot blade of the transfer robot. At step 656, the robot blade of the transfer robot having the substrate thereon is retracted out of the process chamber in the first horizontal transfer plane. In general, the robot blade of the transfer robot in the first horizontal transfer plane is vertically higher than the pop-up position of the set of the lift pins and higher than the second horizontal transfer plane. Thus, at the end of the stage 650, the substrate is disposed on and supported by the robot blade of the transfer robot and removed out of the process chamber.

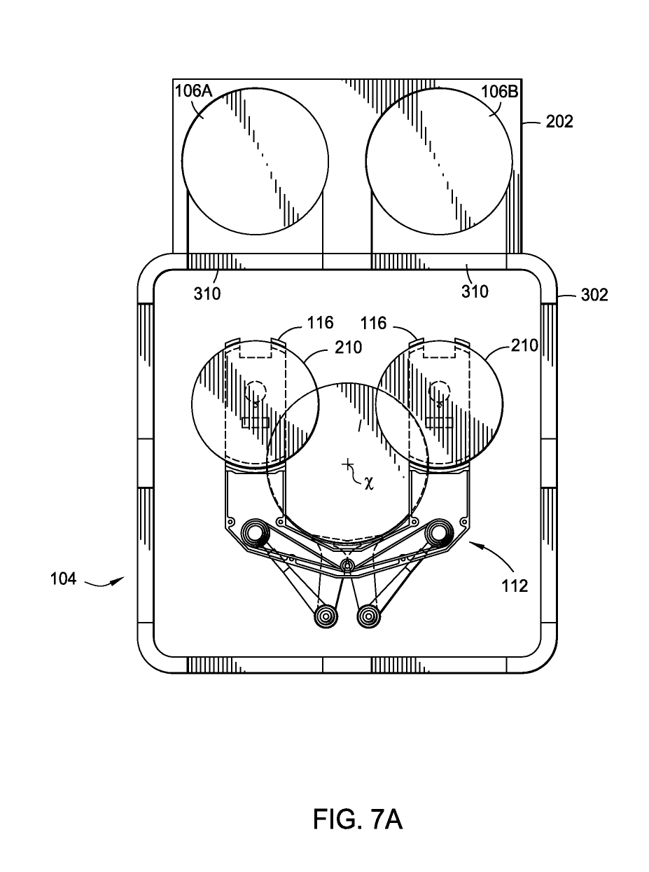

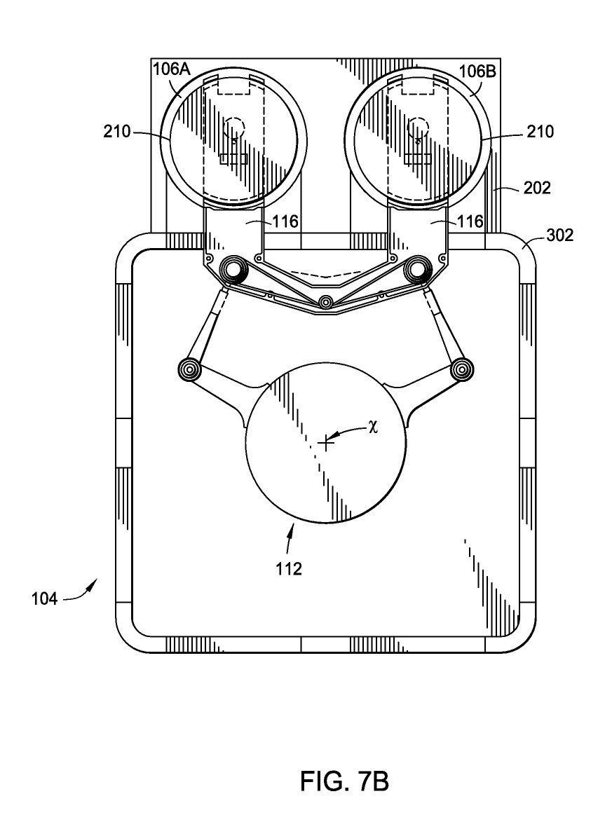

FIG. 7A illustrates a top schematic view of one example of the transfer robot 112, magnetically coupled to the transfer chamber 104 and positioned in a retracted position for freely rotating within the transfer chamber 104 along a central axis “X”. The transfer robot 112 contains dual wafer handling blades (e.g., the robot blades 116) to transfer the substrate 210 from one process chamber to another. One example of the transfer robot 112 which can be modified and used to advantage in the present invention is the subject of U.S. Pat. No. 5,469,035 issued on Nov. 21, 1995, entitled “Two-axis Magnetically Coupled Robot”, and is incorporated herein by reference.

The transfer robot 112 may be a frog-leg type robot assembly connected between two vacuum side hubs (also referred to as magnetic clamps) and dual robot blades 116 to provide both radial and rotational movements of the robot blades 116 within a fixed plane (e.g., in the directions 320, 330 or about the central axis “X”, as shown in FIG. 3A). Radial and rotational movements can be coordinated or combined with vertical movement (e.g., in the direction 340) in order to pickup, transfer and deliver one and/or two substrates 210 from one location within the substrate processing system 100 to another, such as from one process chamber 106 to another chamber. The robot blades 116 can be extended through the passages 310 on the walls 302 of the transfer chamber 104 to transfer the substrate 210 into or out of the processing regions 106A, 106B of the process chamber 106. In general, combinations of motor rotational movements on the transfer robot 112 are used to provide simultaneous extension or retraction of the robot blades 116 being rotated about the central axis “X”.

FIG. 7B shows the robot blades 116 of the example of the transfer robot 112 of FIG. 7A in an extended position. Each robot blade 116 of the transfer robot 112 is sufficiently long to extend through the passage 310 and place the substrate 210 onto (or remove the substrate 210 from) a set of lift pins 250A or 250B, when the set of the lift pins 250A, 250B are in their pop-up position, over the substrate support surface 230 of the support member 220 in the substrate support assembly 240A, 240B. Next, once the substrate 210 is placed onto the lift pins 250A or 250B, the robot blades 116 of the transfer robot 112 is lowered down and retracted back, and the passages 310 are closed by the slit valve 312 and actuator as described above.

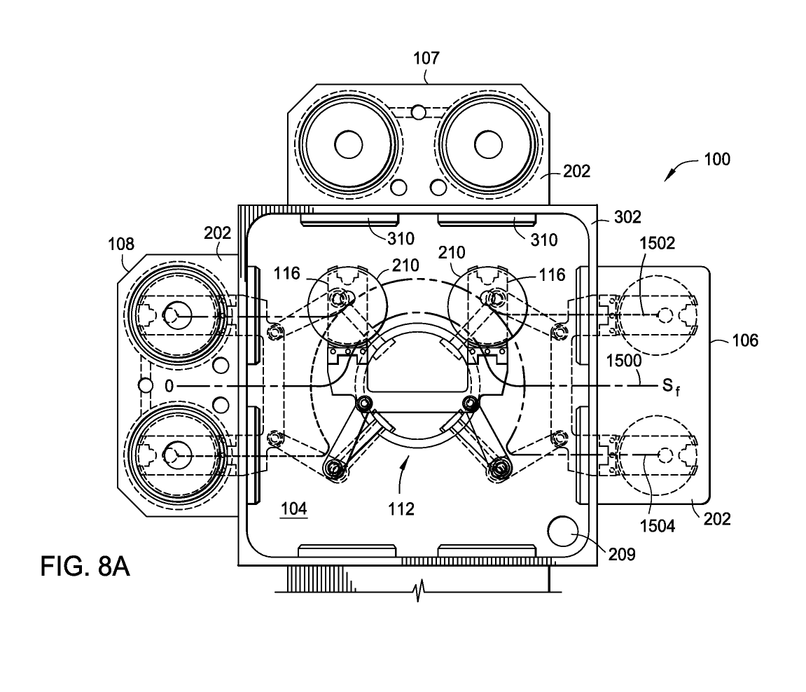

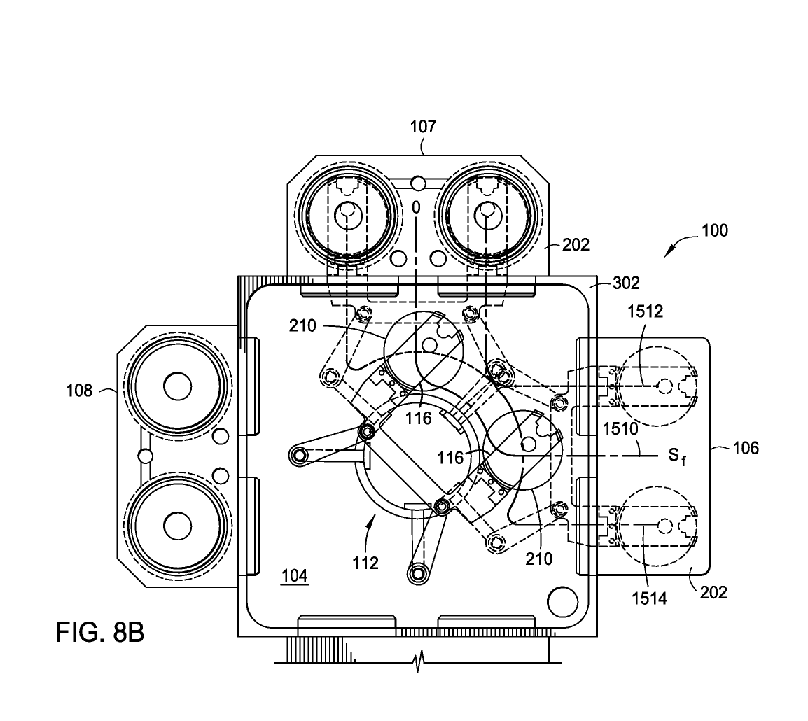

FIG. 8A illustrates a top view of time optimal paths 1500, 1502, 1504 for the transfer robot 112 within the transfer chamber 104, showing the transfer robot moving substrates 210 and rotating between process chambers 106, 108 disposed in opposite positions in a substrate processing system. FIG. 8B illustrates a top view of time optimal paths 1510, 1512, 1514 for the transfer robot 112 within the transfer chamber 104, showing the transfer robot moving substrates 210 and rotating between neighboring process chambers 106, 107.

While the foregoing is directed to embodiments of the present invention, other and further embodiments of the invention can be devised without departing from the basic scope thereof, and the scope thereof is determined by the claims that follow.

1. A substrate processing system having two or more substrate processing regions, comprising:
a first substrate support assembly disposed inside a first substrate processing region;
a first set of lift pins having a first length (L1) and being disposed through the first substrate support assembly;
a second substrate support assembly disposed inside a second substrate processing region;
a second set of lift pins having a second length (L2) and being disposed through the second substrate support assembly, wherein the second length (L2) is different from the first length (L1).

2. The substrate processing system of claim 1, wherein the first set of lift pins are configured to support a substrate transferred thereon in a first stationary position (P1) within the first processing region, while the first substrate support assembly is lowered to a vertically lower substrate transfer position.

3. The substrate processing system of claim 1, wherein the second set of lift pins are configured to support a substrate transferred thereon in a second stationary position (P2) within the second processing region, while the second substrate support assembly is lowered to a vertically lower substrate transfer position.

4. The substrate processing system of claim 1, wherein the first and second set of lift pins are configured to be retracted within the first and the second substrate support assemblies, when the first and the second substrate support assemblies are elevated to a vertically higher substrate processing position.

5. The substrate processing system of claim 1, further comprising a transfer robot configured with two or more robot blades, each blade is configured to move vertically upward and downward and horizontally in a first transfer plane, a second transfer plane and a third transfer plane with each transfer plane spaced a distance apart within the first substrate processing region and the second substrate processing region.

6. The substrate processing system of claim 5, wherein the transfer robot is configured to move vertically and horizontally between the first transfer plane and the second transfer plane for placing and removing a substrate onto and from the first substrate support assembly of the first substrate processing region.

7. The substrate processing system of claim 5, wherein the transfer robot is configured to move vertically and horizontally between the second transfer plane and the third transfer plane for placing and removing a substrate onto and from the second substrate support assembly of the second substrate processing region.

8. The substrate processing system of claim 5, wherein the transfer robot is configured to move vertically and horizontally between the first transfer plane and the third transfer plane for placing and removing two substrates onto and from, one substrate each, the first substrate support assembly and the second substrate support assembly.

9. A process chamber having two or more substrate processing regions, comprising:
a first substrate support assembly disposed inside a first substrate processing region;
a first set of lift pins having a first length (L1) and being disposed in the first substrate support assembly;
a second substrate support assembly disposed inside a second substrate processing region;
a second set of lift pins having a second length (L2) and being disposed in the second substrate support assembly, wherein the second length (L2) is different from the first length (L1).

10. The process chamber of claim 9, wherein the first set of lift pins are configured to support a substrate transferred thereon in a first position (P1) within the first processing region, and the second set of lift pins are configured to support another substrate transferred thereon in a second position (P2) within the second processing region when the first and the second substrate support assemblies are lowered to a vertically lower substrate transfer position.

11. The process chamber of claim 9, wherein the first and second set of lift pins are configured to be retracted within the first and the second substrate support assemblies when the first and the second substrate support assemblies are elevated to a vertically higher substrate processing position.

12. The process chamber of claim 9, further comprising a transfer robot configured with two or more robot blades, each blade configured to move vertically upward and downward and horizontally in three transfer planes within the first substrate processing region and the second substrate processing region.

13. The process chamber of claim 12, wherein the transfer robot is configured to independently load one substrate onto one of the first and the second substrate support assemblies.

14. The process chamber of claim 12, wherein the transfer robot is configured to simultaneously transfer two substrates in and out of the first and the second substrate support assemblies.

15. The process chamber of claim 9, wherein the process chamber is a chamber selected from the group consisting of etch chambers, cleaning chambers, CVD chambers, PVD chambers, ALD chambers, and combinations thereof.

16. A method for processing a substrate in a process chamber, comprising:
positioning a substrate support assembly to a vertically lower substrate transfer position such that a set of lift pins is positioned in a pop-up position configured to extend upwardly in its length above a surface of a bottom chamber body of the process chamber, pass through the substrate support assembly and extend vertically a distance above a substrate support surface of the substrate support assembly;
transferring a substrate inside the process chamber in a first horizontal transfer plane,
placing the substrate onto a set of lift pins positioned in the pop-up position by vertically lowering the substrate; and
engaging the substrate onto the substrate support surface of the substrate support assembly by vertically elevating the substrate support assembly and retracting the set of lift pins within the substrate support assembly into a retracted position.

17. The method of claim 16, further comprising positioning the substrate support assembly to a vertically higher substrate processing position.

18. The method of claim 16, wherein a transfer robot is configured to transfer the substrate inside the process chamber in the first horizontal transfer plane.

19. The method of claim 18, further comprising:
vertically moving the transfer robot downward and placing the substrate onto the set of lift pins positioned in the pop-up position; and
retracting the transfer robot out of the process chamber in a second horizontal transfer plane that is vertically lower than the first horizontal transfer plane.

20. The method of claim 16, further comprising;
positioning the substrate support assembly to the vertically lower substrate transfer position after the substrate is processed in the process chamber by vertically lowering the substrate and positioning the set of lift pins from the retracted position to the pop-up position;
placing the substrate onto the set of lift pins positioned in the pop-up position;
moving a transfer robot inside the process chamber in the second horizontal transfer plane which is vertically lower than the pop-up position of the set of the lift pins;
placing the substrate onto the transfer robot by vertically moving the transfer robot upward; and
removing the substrate out of the transfer chamber by retracting the transfer robot in the first horizontal transfer plane which is vertically higher than the pop-up position of the set of the lift pins and higher than the second horizontal transfer plane.
